(19) United States
(12) Patent Application Publication
(10) Pub. No.: US 2021/0157407 A1
(43) Pub. Date: May 27, 2021

(54) TOUCH SURFACE ASSEMBLY WITH HAPTIC CAPABILITY AND SUSPENSION COMPONENTS

(71) Applicant: Immersion Corporation, San Jose, CA (US)

(72) Inventors: Peyman KARIMI ESKANDARY, Montreal, QC (CA); Jamal SABOUNE, Montreal, QC (CA); Juan Manuel CRUZ HERNANDEZ, Montreal, QC (CA)

(21) Appl. No.: 16/692,107

(22) Filed: Nov. 22, 2019

(51) Int. Cl. G06F 3/01; G06F 3/041; H01L 41/09

(52) U.S. Cl. CPC G06F 3/016; H01L 41/0926; G06F 3/0412

(57) ABSTRACT

In aspects, a touch surface assembly and a method of providing thereof are provided. For example, a touch surface assembly includes a touch surface, a haptic actuator configured to provide a linear motion along a motion axis of the haptic actuator to provide a haptic effect on the touch surface, and coupled to the touch surface such that the motion axis of the haptic actuator forms an angle with a centerline of the touch surface, and suspension components configured to provide damping with resonance for a motion of the touch surface. A first set of at least two suspension components of the suspension components are coupled to the touch surface along or substantially along the motion axis, and a second set of at least two suspension components of the suspension components are coupled to the touch surface along or substantially along a neutral axis of the haptic actuator that is perpendicular to the motion axis.

### FIELD OF THE INVENTION

The present invention is directed to a touch surface assembly having a touch surface, a haptic actuator for providing a haptic effect on the touch surface, and suspension components to reduce and/or eliminate an unwanted motion of the touch surface.

### BACKGROUND

A touch surface capable of receiving a touch input has been widely used for various applications. In one example, the touch surface may be implemented as a surface to receive a touch input from a user, such as a touch pad for a laptop computer. In another example, the touch surface may be implemented with a display device to form a touch screen. The touch surface may be provided with a haptic actuator coupled thereto, to provide a haptic effect on the touch surface. For example, the touch surface may experience a motion or a vibration caused by the haptic actuator. Various efforts are being made to improve a haptic effect provided on a touch surface and experienced by a user.

### SUMMARY

According to an aspect hereof, a touch surface assembly is disclosed with a haptic capability. The touch surface assembly may include a touch surface configured to receive a touch input and may further include a haptic actuator configured to provide a linear motion along a motion axis of the haptic actuator to provide a haptic effect on the touch surface, wherein the haptic actuator is coupled to the touch surface such that the motion axis of the haptic actuator forms an angle with a centerline of the touch surface. The touch surface assembly may further include a plurality of suspension components configured to provide damping with resonance for a motion of the touch surface, where a first set of at least two suspension components of the plurality of suspension components are coupled to the touch surface along or substantially along the motion axis of the haptic actuator, and a second set of at least two suspension components of the plurality of suspension components are coupled to the touch surface along or substantially along a neutral axis of the haptic actuator that is perpendicular to the motion axis.

According to an aspect hereof, a method of providing a touch surface assembly with a haptic capability is disclosed. The method may include employing a touch surface configured to receive a touch input, and may further include employing a haptic actuator configured to provide a linear motion along a motion axis of the haptic actuator to provide a haptic effect on the touch surface, wherein the haptic actuator is coupled to the touch surface such that the motion axis of the haptic actuator forms an angle with a centerline of the touch surface. The method may further include placing, on the touch surface, a plurality of suspension components configured to provide damping with resonance for a motion of the touch surface, where a first set of at least two suspension components of the plurality of suspension components are coupled to the touch surface along or substantially along the motion axis of the haptic actuator, and a second set of at least two suspension components of the plurality of suspension components are coupled to the touch surface along or substantially along a neutral axis of the haptic actuator that is perpendicular to the motion axis.

Numerous other aspects are provided.

### BRIEF DESCRIPTION OF THE DRAWINGS

The foregoing and other features, objects and advantages of the invention will be apparent from the following description of aspects hereof as illustrated in the accompanying drawings. The accompanying drawings, which are incorporated herein and form a part of the specification, further serve to explain the principles of the invention and to enable a person skilled in the pertinent art to make and use the invention. The drawings are not to scale.

FIG. 1A depicts a block diagram of a touch surface assembly capable of providing a haptic effect, according to an aspect hereof.

FIG. 1B depicts a block diagram of a touch surface assembly including a touch surface, a haptic actuator, and suspension components, wherein the haptic actuator and the suspension components are disposed on the touch surface, according to an aspect hereof.

FIG. 2A is an illustration of a perspective view of a touch surface assembly.

FIG. 2B is an illustration of an exemplary bottom-face view of the touch surface assembly of FIG. 2A without a base.

FIG. 3A is an illustration of a perspective view of a touch surface assembly, according to an aspect hereof.

FIG. 3B is an illustration of an exemplary bottom-face view of the touch surface assembly of FIG. 3A without a base, according to an aspect hereof.

FIG. 4 is another illustration of an exemplary bottom-face view of a touch surface assembly without a base, according to an aspect hereof.

FIG. 5A is an illustration of a perspective view of a touch surface assembly, including first, second, and third sets of suspension components, according to an aspect hereof.

FIG. 5B is an illustration of an exemplary bottom-face view of the touch surface assembly of FIG. 5A without a base, according to an aspect hereof.

FIG. 6 is an illustration of an exemplary bottom-face view of a touch surface assembly without a base, according to an aspect hereof.

FIG. 7 is an illustration of an exemplary bottom-face view of a touch surface assembly without a base, according to an aspect hereof.

FIG. 8 illustrates experimental results using a touch surface assembly of the disclosure, according to an aspect hereof.

FIG. 9 depicts a flow diagram of a method for providing a touch surface with a haptic capability, according to an aspect hereof.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

A haptic actuator may be configured to provide a motion, for example, vibration, in a direction along a motion axis of the haptic actuator. Examples of such a haptic actuator may include a linear resonant actuator (LRA) and a direct-drive actuator such as a piezoelectric actuator and a solenoid-based actuator. A haptic actuator may be provided with a touch surface such as a touch pad, for example, without a visual display, or a touch screen, for example, with a visual display, so as to provide a motion-related haptic effect on the touch surface. For example, as a finger(s) moves on the touch surface, for example, by sliding, pinching, zooming in/out, or dragging, the haptic actuator may generate a motion to cause a haptic effect on the touch surface, which can be felt by the finger(s) on the touch surface.

If a direction of a touch motion of a user, for example, by a finger(s), on a touch surface is substantially parallel to a motion axis of a haptic actuator, a haptic effect felt by the user, for example, the user's finger(s), may be diminished. Assuming that common directions of the touch motion are in a horizontal direction and a vertical direction with respect to a centerline of the touch surface, in order to minimize such a diminished haptic effect, the haptic actuator may be placed such that the motion axis of the haptic actuator is at an angle, for example, a diagonal orientation, from the centerline of the touch surface, for example, with respect to a viewing orientation. In accordance with aspects hereof, for example, if a motion axis of a haptic actuator is at an angle, a touch motion in a horizontal direction or a vertical direction may not experience diminished haptic effect. In accordance with aspects hereof, for example, where a touch surface is a rectangular shape, a haptic actuator may be positioned at a center of the touch surface at an angle with a centerline of the touch surface such that a motion axis of the haptic actuator is at a 45 degree angle or at a diagonal orientation with respect to the centerline.

Ideally in an aspect hereof, a motion of a haptic effect caused by a haptic actuator should only occur along a motion axis of the haptic actuator and should be stopped at a desired time. However, prior to aspects described herein, an unwanted motion on a touch surface may exist outside of a motion axis while a haptic actuator causes a motion along the motion axis. Further heretofore, when a haptic effect is no longer desired, a brake and/or braking action may be employed to act on a haptic actuator to prevent further motion by the haptic actuator and to provide a sharp crisp haptic effect. In such an instance, a controller, for example, a closed-loop controller, configured to control the haptic actuator and stop any motion of a haptic effect along a motion axis may be implemented. However even with such measures, prior to aspects described herein, unwanted residual motion may still exist along a motion axis and/or outside of a motion axis of a haptic actuator, after a brake and/or a braking action is implemented on the haptic actuator.

More particularly, motion caused by a haptic actuator that is outside of a motion axis may adversely affect the quality of a haptic effect, and thus may be considered an unwanted motion. For example, unwanted motion may include at least a motion along another axis, for example, the neutral axis, different from a motion axis and/or a rotational motion about a center of a touch surface or other portions of the touch surface. Because unwanted motion is not along a motion axis, a controller that provides braking of a haptic actuator's motion along the motion axis may not be able to provide sufficient braking to reduce or eliminate the unwanted motion. Thus, a haptic actuator may not be able to provide a high quality haptic effect if a touch surface experiences motion that is not along a motion axis of the haptic actuator. Unwanted motion that occurs not along a motion axis of a haptic actuator may mainly exist along or near a neutral axis of the haptic actuator, wherein the neutral axis is perpendicular to the motion axis of the haptic actuator.

Suspension components may be placed on the touch surface to effectively control a motion of a touch surface, where each suspension component may have a spring feature (e.g., via resonating or oscillating) and/or a damper feature (e.g., via damping). By providing a damper feature with a resonance of a spring feature, suspension components may be capable of gradually reducing a motion of a touch surface with oscillation. In an example where a touch surface is a rectangle and a haptic actuator is mounted at an angle, for example, 45 degrees or diagonally with respect to a centerline of the touch surface, suspension components may be placed at four corners of the touch surface. Thus, in this example, suspension components are not located along axes where a majority of motion of a touch surface occurs.

In an aspect hereof, it has been recognized that unless suspension components are placed along or substantially along axes where a majority of motion to be addressed by the suspension components occurs, the suspension components may not effectively control the motion of a touch surface. In an aspect hereof, a majority of motion of a touch surface has been recognized to occur along a motion axis and a neutral axis of a haptic actuator, and thus in accordance with aspects hereof suspension components may be placed on the motion axis and/or the neutral axis of the haptic actuator. In aspects hereof, for example, unwanted motion has been recognized to likely be generated along a neutral axis of a haptic actuator before or after braking of the haptic actuator and unwanted residual motion may also exist along a motion axis of the haptic actuator after braking of the haptic actuator. Thus, according to an aspect hereof, a first set of suspension components may be placed on a motion axis of a haptic actuator for effective braking of the haptic actuator. Further, according to an aspect hereof, to address unwanted motion along a neutral axis of the haptic actuator that is perpendicular to the motion axis, a second set of the suspension components may be placed on the neutral axis of the haptic actuator.

In aspects hereof, for certain applications, a second set of suspension components may be placed on the neutral axis of the haptic actuator to be substantially symmetric to each other with respect to the motion axis. In aspects hereof, a first set of suspension components may be placed on a motion axis of a haptic actuator to be substantially symmetric to each other with respect to a neutral axis. In aspects hereof, such symmetries of suspension components may allow a clean haptic effect whose motion exists mainly on the motion axis of the haptic actuator and does not exist in other axes, for example, by allowing vibration along only the motion axis.

In accordance with aspects hereof, in certain applications, a third set of suspension components may be placed on a touch surface to address unwanted motion that is not sufficiently addressed by a first set of suspension components and a second set of suspension components. In an aspect in accordance herewith, for example, in the aforementioned example where a touch surface is a rectangle, a first set of suspension components may be placed on or substantially on a motion axis at or near two corners of a touch surface, respectively, and a second set of suspension components may be placed on a neutral axis, for example, along or substantially along an edge of the rectangular touch surface, that is not on or near any corners of the rectangular touch surface. Since it has been found as an aspect hereof that unwanted motion may occur near the two corners of the touch surface with no suspension components thereon, in an aspect hereof, the third set of suspension components may be placed at these two corners. In an aspect, the third set of suspension components may not substantially overlap with the motion axis or the neutral axis of the haptic actuator but instead may be placed outside of the motion axis and/or the neutral axis.

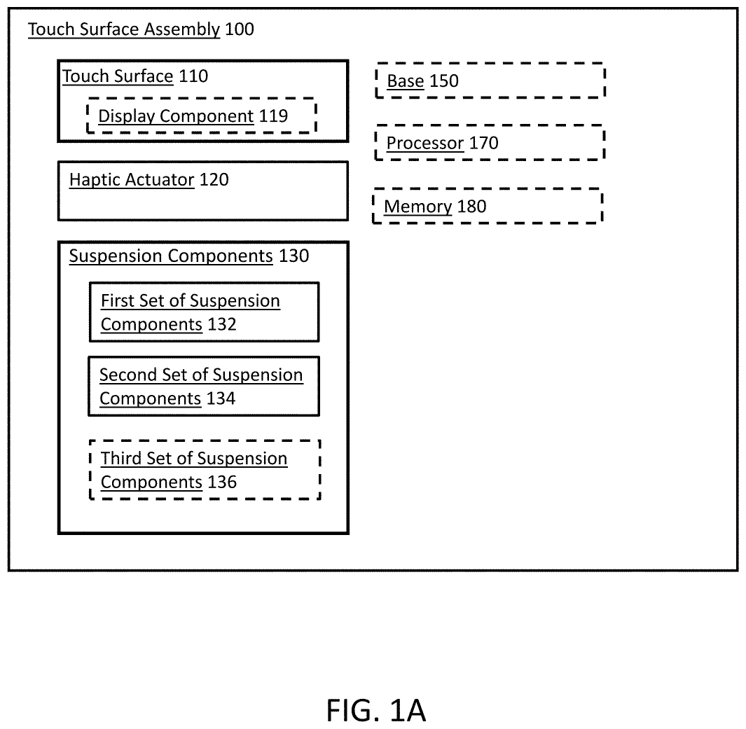

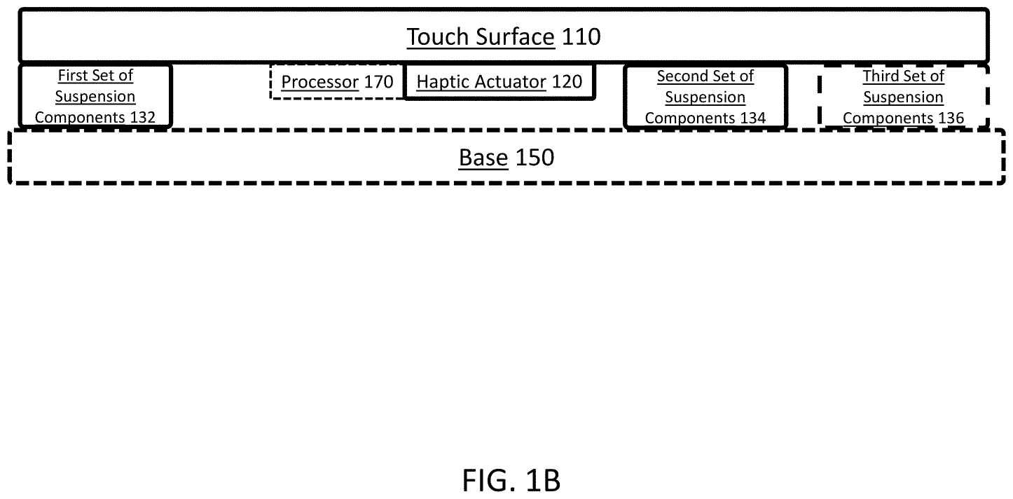

More detailed features of a touch surface assembly in accordance with aspects hereof are described below in conjunction with various figures. FIG. 1A illustrates a block diagram of a touch surface assembly 100, according to an aspect hereof. The touch surface assembly 100 includes a touch surface 110, a haptic actuator 120, and suspension components 130. In aspects hereof, the suspension components are configured to reduce or eliminate a motion of the touch surface, to provide a stiffness element for the assembly, and to hold the touch surface in a floating manner. The suspension components 130 include a first set of suspension components 132 and a second set of suspension components 134. In some aspects, the suspension components 130 may include a third set of suspension components 136. The touch surface assembly 100 may further include a base 150, a memory 180, and a processor 170.

FIG. 1B depicts a block diagram of a touch surface assembly including the touch surface 110, the haptic actuator 120, and the suspension components 130, where the haptic actuator 120 and suspension components 130 are disposed on the touch surface 110, according to aspects hereof. As shown in FIG. 1B, a first set of suspension components 132 and a second set of suspension components 134 are coupled to the touch surface 110. A third set of suspension components 136 may also be disposed on the touch surface 110. The haptic actuator 120 is coupled to the touch surface 110, such that the movement caused by the haptic actuator 120 along a motion axis of the haptic actuator 120 may cause motion on the touch surface 110. The processor 170 may be coupled to the haptic actuator 120 to control the haptic actuator 120. The first set of suspension components 132, the second set of suspension components 134, and the third set of suspension components 136 may be disposed on the base 150.

The touch surface 110 is a device capable of receiving a touch input, for example, a touch by a user. The touch surface 110 may include touch sensors configured to detect a touch in areas respectively associated with the touch sensors. The touch sensors for the touch surface 110 may be resistive and/or capacitive sensors embedded in the touch surface 110 and may be used to determine a location of a touch on the touch surface 110. The touch surface 110 may be implemented within a device such as a laptop, a car infotainment display, a home appliance device, etc. Examples of the touch surface 110 may include a touch pad that is configured to receive a touch input and a touch screen that is configured to receive a touch input and to display information. For example, optionally, a touch surface 110 may include a display component 119 configured to display information, thereby forming the touch screen.

The haptic actuator 120 is a device capable of providing a haptic effect. In particular, the haptic actuator 120 may be configured to cause movement of the touch surface 110 as a haptic effect. For example, the haptic actuator 120 may be configured to provide a linear motion along a motion axis of the haptic actuator 120 to provide a haptic effect on the touch surface 110. As discussed above, examples of the haptic actuator 120 may include an LRA device where a mass may be driven linearly along the motion axis and/or a direct-drive device that is actuated to provide a linear motion along the motion axis. Further, the haptic actuator 120 may be coupled to the touch surface 110 such that the motion axis of the haptic actuator 120 forms an angle with a centerline of the touch surface 110. The centerline of the touch surface 110 may be a straight line that is horizontal with respect to a viewing orientation of the touch surface 110. Because the haptic actuator 120 is coupled to the touch surface 110, the linear motion of the haptic actuator 120 along the motion axis may cause motion, for example, vibration, of the touch surface 110. Thus, in an aspect, the motion of the touch surface 110 may be perceived by a user touching the touch surface 110 as a haptic effect.

In accordance with aspects hereof, when a haptic effect causing motion of the touch surface 110 is provided by the haptic actuator 120, unwanted motion of the touch surface 110 is addressed by the suspension components 130. For example, because the suspension components 130 may reduce or eliminate the unwanted motion of the touch surface 110, the motion on the touch surface 110 caused by the haptic actuator 120 may exist only or mostly along the motion axis of the haptic actuator 120, which provides a clean haptic effect. Examples of the unwanted motion addressed by the suspension components 130 may include the motions in directions other than the motion axis while the haptic actuator 120 is activated and/or a residual unwanted motion that lingers on the haptic actuator 120 after the haptic actuator 120 is deactivated, along the motion axis and/or other axes. The suspension components 130 are configured to provide damping with resonance for a motion of the touch surface 110. For example, each of the suspension components 130 may provide a damper feature that damps the motion of the touch surface 110 caused by the haptic actuator 120, with a spring feature having a resonance to allow oscillation for the motion of the touch surface 110. As such, in an aspect hereof, the suspension components 130 may provide a stiffness to the touch surface assembly that reduces or eliminates unwanted motion on the touch surface 110, thereby providing an improved haptic effect. In one example, the suspension components 130 may be in a form of flat suspension pads attached to the touch surface 110 and having a certain thickness, for example, 0.5 mm, 0.75 mm, 1 mm, or 1.5 mm. In this example, the suspension pads may be in any 3D shape, including a cube, a cylinder, and a cuboid. In aspects in accordance herewith, the suspension components 130 may be made of at least one of an elastomer device, for example, made of an elastomer material such as silicon, a flexure device capable of providing a damper feature and a spring feature, a spring-based device, and/or any other materials or structures that can provide both the damper feature and the spring-like feature. For example, the suspension components 130 may gradually reduce the motion of the touch surface 110 by providing damping of the movement of the touch surface 110 while allowing the touch surface 110 to move in oscillation, for example, for a smooth transition.

With reference to FIG. 1B, the suspension components 130 coupled to the touch surface 110 may be disposed on the base 150. In an aspect, the base 150 may act as a mechanical ground, which may disperse force or motion transferred to the base 150 via the suspension components 130. Thus, the motion on the touch surface 110 caused by the haptic actuator 120 may be transferred, at least in part, to the base 150 via the suspension components 130. The base 150 may be any structure to which the touch surface is coupled via the suspension components 130. For example, if the touch surface 110 is a car infotainment display, the base 150 may be a body of the car infotainment system to which the car infotainment display is attached via suspension components.

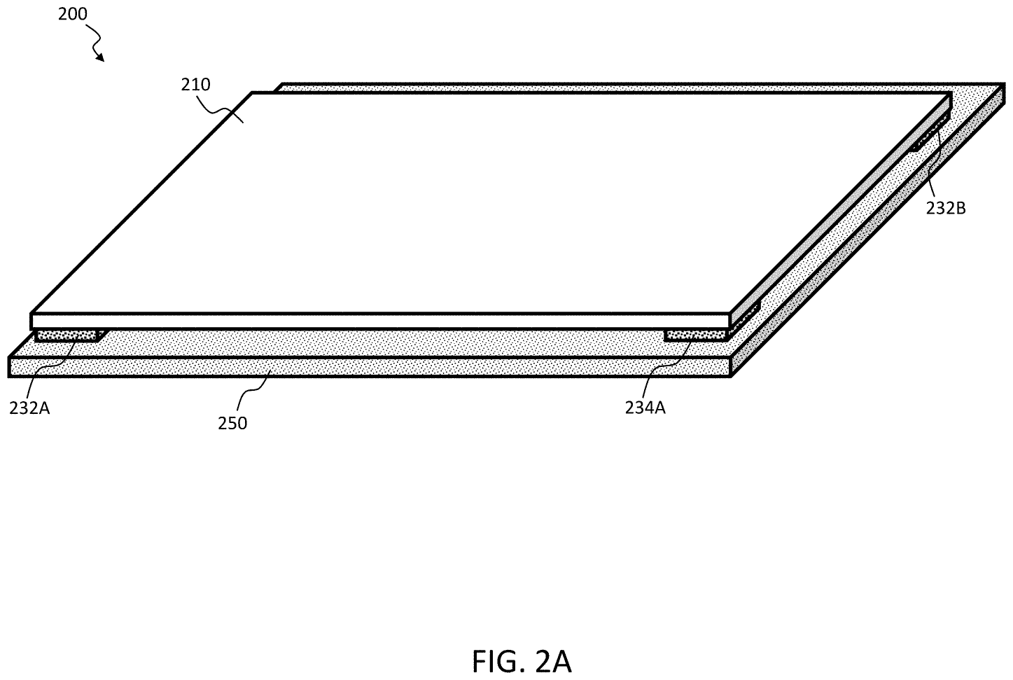

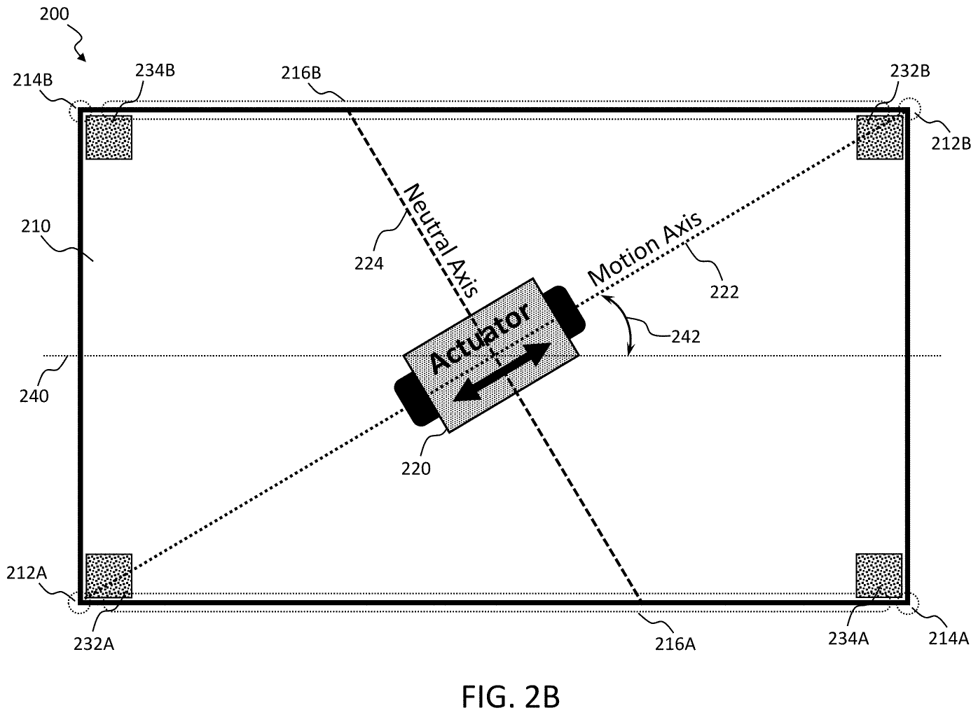

FIG. 2A is an illustration of a perspective view of a touch surface assembly 200. FIG. 2B is an illustration of an exemplary bottom-face view of the touch surface assembly 200 without a base. The touch surface assembly 200 includes a touch surface 210, a first set of suspension components 232A, 232B and a second set of suspension components 234A, 234B coupled to a bottom of the touch surface 210, and a haptic actuator 220 coupled to the bottom of the touch surface 210. The touch surface assembly 200 may also include a base 250 on which the touch surface 210 rests via the first set of suspension components 232A, 232B and the second set of suspension components 234A, 234B.

In FIGS. 2A and 2B, the first set of suspension components 232A, 232B are respectively disposed near corners 212A, 212B of the touch surface 210, while the second set of suspension components 234A, 234B are respectively disposed near corners 214A, 214B of the touch surface 210. The haptic actuator 220 is disposed on the touch surface 210 at an angle, such that a motion axis 222 of the haptic actuator 220 forms an angle 242 with a centerline 240 of the touch surface 210. As shown in FIG. 2B, the motion axis 222 crosses opposing corners 212A, 212B of the touch surface 210. Because the first set of suspension components 232A, 232B are disposed along or substantially along the motion axis 222, respectively at the opposing corners 212A, 212B, motion along the motion axis 222 caused by the actuator 220 may be addressed by the first set of suspension components 232A, 232B. On the other hand, a neutral axis 224 of the haptic actuator 220 that is perpendicular to the motion axis 222 crosses opposing sides 216A, 216B that form a portion of a perimeter of the touch surface 210, and the neutral axis 224 thus does not cross the remaining corners 214A, 214B of the touch surface 210. The second set of suspension components 234A, 234B are respectively disposed near the second corners 214A, 214B, which are located away from the neutral axis 224. In the example shown in FIGS. 2A and 2B, because the second set of suspension components 234A, 234B or any other suspension components are not disposed along or substantially along the neutral axis 224 of the haptic actuator 220, the unwanted motion along the neutral axis 224 caused by the actuator 220 may not be sufficiently addressed.

In aspects in accordance herewith, referring back to FIG. 1A, the suspension components 130 may include the first set of suspension components 132 and the second set of suspension components 134 that are positioned to address different types of motion of the touch surface 110. In an aspect hereof, the first set of suspension components 132 may include at least two suspension components and the second set of suspension components 134 may include at least two suspension components. The first set of suspension components 132 may be coupled to the touch surface 110 along or substantially along a motion axis of the haptic actuator 120. Thus, the first set of suspension components 132 may reduce or eliminate the unwanted motion of the touch surface 110 along the motion axis of the haptic actuator 120. The second set of suspension components 136 may be coupled to the touch surface 110 along or substantially along a neutral axis of the haptic actuator 120 that is perpendicular to the motion axis. Thus, the second set of suspension components 134 may reduce or eliminate unwanted motion of the touch surface 110 along the neutral axis of the haptic actuator 120. In some aspects, the motion axis and the neutral axis of the haptic actuator 120 may be aligned with a center of the haptic actuator.

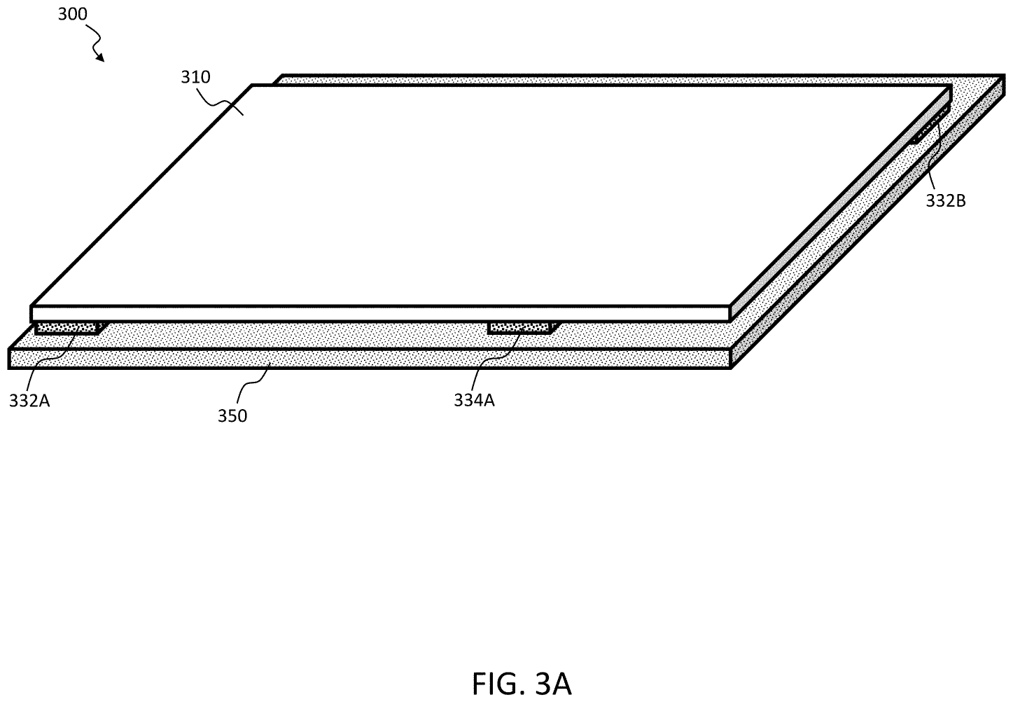

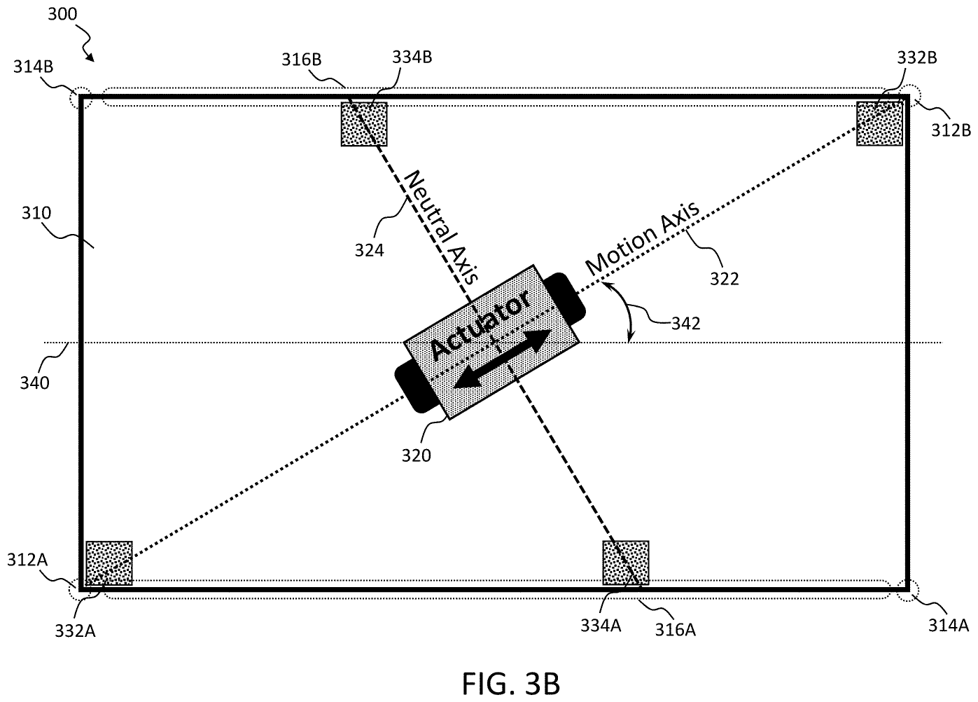

FIG. 3A is an illustration of a perspective view of a touch surface assembly 300, according to aspects hereof. FIG. 3B is an illustration of an exemplary bottom-face view of the touch surface assembly 300 without a base, according to aspects hereof. The touch surface assembly 300 includes a touch surface 310, a first set of suspension components 332A, 332B and a second set of suspension components 334A, 334B coupled to a bottom of the touch surface 310, and a haptic actuator 320 coupled to the bottom of the touch surface 310. The touch surface assembly 300 may also include a base 350 on which the touch surface 310 rests via the first set of suspension components 332A, 332B and the second set of suspension components 334A, 334B. The touch surface assembly 300 may be an example of the touch surface assembly 100 of FIG. 1A. Therefore, the features of the touch surface 310, the haptic actuator 320, and the first set of suspension components 332A, 332B, the second set of suspension components 334A, 334B, and the base 350 may correspond to the touch surface 110, the haptic actuator 120, and the first set of suspension components 132, the second set of suspension components 134, and the base 150 of FIG. 1A and thus detailed discussions of the touch surface 310, the haptic actuator 320, and the first set of suspension components 332A, 332B, the second set of suspension components 334A, 334B, and the base 350 are partially omitted for brevity.

The haptic actuator 320 is configured to provide a linear motion along a motion axis 322 of the haptic actuator 320 to provide a haptic effect on the touch surface 310. As shown in FIG. 3B, the haptic actuator 320 is disposed on the touch surface 310 at an angle, such that the motion axis 322 of the haptic actuator 320 forms an angle 342 with a centerline 340 of the touch surface 310. The first set of suspension components 332A, 332B are coupled to the touch surface 310 along or substantially along the motion axis 322, so as to address the motion on the touch surface 310 along the motion axis 322. The second set of suspension components 334A, 334B are coupled to the touch surface 310 along or substantially along the neutral axis 324 of the haptic actuator 320 that is perpendicular to the motion axis 322, so as to address the motion on the touch surface 310 along the neutral axis 324.

Depending on an orientation of a haptic actuator 120, a motion axis and/or a neutral axis of the haptic actuator 120 may not align with a corner of a touch surface 110. If the neutral axis of the haptic actuator 120 does not align with any corner of the touch surface 110, a set of suspension components may be disposed on non-corner portions of the touch surface 110. Thus, in an aspect, the at least two suspension components of the set may be disposed at or near opposing sides of the touch surface 110, respectively. In some cases, even if a neutral axis of a haptic actuator 120 does not align with any corner of a touch surface 110, a motion axis may be aligned with corners of a touch surface 110. In an aspect, the haptic actuator 120 may be disposed on the touch surface 110 such that the motion axis of the haptic actuator 120 is located on a diagonal line between two corners on the touch surface 110. In some cases, if the motion axis of the haptic actuator 120 does not align with any corner of the touch surface 110, a set of suspension components may be disposed on non-corner portions of the touch surface 110. Thus, in an aspect, the at least two suspension components of a set of suspension components may be disposed at or near opposing sides of the touch surface 110, respectively.

For example, as shown in FIG. 3B, because of a shape of the touch surface 310 and the orientation of the haptic actuator 320 on the touch surface 310, the second set of suspension components 334A, 334B are disposed near opposing sides 316A, 316B, respectively, that form a portion of a perimeter of the touch surface 310. In FIG. 3B, the haptic actuator 320 is disposed on the touch surface 310 at an angle such that the motion axis 322 of the haptic actuator 310 is located on a diagonal line between opposing corners 312A, 312B on the touch surface 310, and the first set of suspension components 312A, 312B are disposed near the opposing corners 312A, 312B, respectively.

When a touch surface 110 is divided into two portions based on a motion axis of a haptic actuator 120, these two portions may be asymmetric to each other with respect to the motion axis. Thus, in an aspect, a first portion of the touch surface 110 located on one side of the motion axis of the haptic actuator 120 and a second portion of the touch surface 110 located on an opposite side of the motion axis may be asymmetric to each other with respect to the motion axis. Further, when a touch surface 110 is divided into two portions based on a neutral axis of a haptic actuator 120, these two portions may be asymmetric to each other with respect to the neutral axis. Thus, in an aspect, a third portion of the touch surface 110 located on one side of the neutral axis of the haptic actuator 120 and a fourth portion of the touch surface 110 located on an opposite side of the neutral axis may be asymmetric to each other with respect to the neutral axis.

In one example, a touch surface 110 may be a rectangular shape and a haptic actuator 120 may be placed such that a motion axis of the haptic actuator 120 aligns with a diagonal line between two corners of the haptic actuator 120. In this example, a first portion of the touch surface 110 located on one side of the motion axis and a second portion of the touch surface 110 located on the opposite side of the motion axis are asymmetric to each other with respect to the motion axis. Further, in this example, a third portion of the touch surface 110 located on one side of a neutral axis and a fourth portion of the touch surface 110 located on an opposite side of the neutral axis are asymmetric to each other with respect to the neutral axis.

In an aspect, corners of the touch surface 110 may be asymmetrically disposed to each other with respect to either of a motion axis and/or a neutral axis. In the above-discussed example where the touch surface 110 is rectangular shaped and the motion axis of the haptic actuator 120 aligns with a diagonal line between two corners of the haptic actuator 120, the two corners that are diagonally facing each other are asymmetrically disposed to each other with respect to the neutral axis of the haptic actuator 120 and the other two corners, not on the diagonal line, are asymmetrically disposed to each other with respect to the motion axis of the haptic actuator 120.

For example, as shown in FIG. 3B, because of a shape of the touch surface 310 and an orientation of the haptic actuator 320 on the touch surface 310, if the touch surface 310 is divided by the motion axis 322 into a top left portion and a bottom right portion, the top left portion of the touch surface 310 is asymmetric to the bottom right portion of the touch surface 310 with respect to the motion axis 322. If the touch surface 310 is divided by the neutral axis 324 into a left portion and a right portion, the left portion of the touch surface 310 is asymmetric to the right portion of the touch surface 310 with respect to the neutral axis 324. In addition, the corners 312A, 312B of the touch surface 310 are asymmetrically disposed to each other with respect to the neutral axis 324. The remaining corners 314A, 314B of the touch surface 310 are asymmetrically disposed to each other with respect to the motion axis 322 and with respect to the neutral axis 324.

In an aspect, referring back to FIG. 1A, a second set of suspension components 134 of the suspension components 130 may be disposed on the touch surface 110 along or substantially along the neutral axis of the haptic actuator to be substantially symmetric to each other with respect to the motion axis of the haptic actuator 120. For example, the symmetry of the second set of suspension components 134 with respect to the motion axis may allow clean reduction of unwanted motion of the touch surface 110 along the neutral axis, which may occur while the haptic actuator 120 is activated and/or after braking of the haptic actuator 120. By reducing the unwanted motion of the touch surface 110 along the neutral axis, the unwanted motion's interference with the haptic effect by the haptic actuator 120 is reduced and thus a stronger motion along the motion axis caused by the haptic actuator 120 may be observed while the haptic actuator 120 is activated. Further, in this aspect, a first set of suspension components 132 of the suspension components 130 may be disposed on the touch surface 110 along or substantially along a motion axis of the haptic actuator 120 to be substantially symmetric to each other with respect to a neutral axis of the haptic actuator 120. For example, the symmetry of the first set of suspension components 132 with respect to the neutral axis may allow clean reduction of unwanted motion of the touch surface 110 along the motion axis, such as unwanted residual motion after braking of the haptic actuator 120.

For example, as shown in FIG. 3B, the suspension component 332A and the suspension component 332B of the first set are disposed on the touch surface 310 to be substantially symmetric to each other with respect to a neutral axis 324, such that a balance of the suspension component 332A and the suspension component 332B with respect to the neutral axis 324 may be achieved. Further, for example, as shown in FIG. 3B, the suspension component 334A and the suspension component 334B of the second set are disposed on the touch surface 310 to be substantially symmetric to each other with respect to the motion axis 322 such that a balance of the suspension component 334A and the suspension component 334B with respect to the motion axis 322 may be achieved.

In an aspect, a symmetry of suspension components with respect to an axis is formed when there is a symmetry of areas covered by the suspension components. In one example, a symmetry with respect to an axis may be provided when position(s) of suspension component(s) at one side of an axis match position(s) of suspension component(s) at the other opposing side of the axis and a number of suspension component(s) at one side of the axis may be equal to a number of suspension component(s) at the other, opposing side of the axis. For example, as shown in FIG. 3B, the position of the suspension component 332A at one side of the neutral axis 324 matches the position of the suspension component 332B at the opposing side of the neutral axis 324, and there is one suspension component on each side of the neutral axis 324. Further, for example, as shown in FIG. 3B, the position of the suspension component 334A at one side of the motion axis 322 matches the position of the suspension component 334B at the opposing side of the motion axis 322, and there is one suspension component on each side of the motion axis 322.

In another example, a number of suspension components at one side of an axis may be different from a number of suspension components at the other, opposing side of the axis. In such an example, a size of the suspension components at one side of the axis may be different from that of the suspension components at the other, opposing side of the axis, such that a symmetry in the effect of the suspension components may be achieved with respect to the axis. For example, two small suspension components may be disposed at one side of an axis while one large suspension component may be disposed at the other side of the axis, where a size of the two small suspension components combined may be equal to a size of the large suspension component, forming a symmetry with respect to the axis.

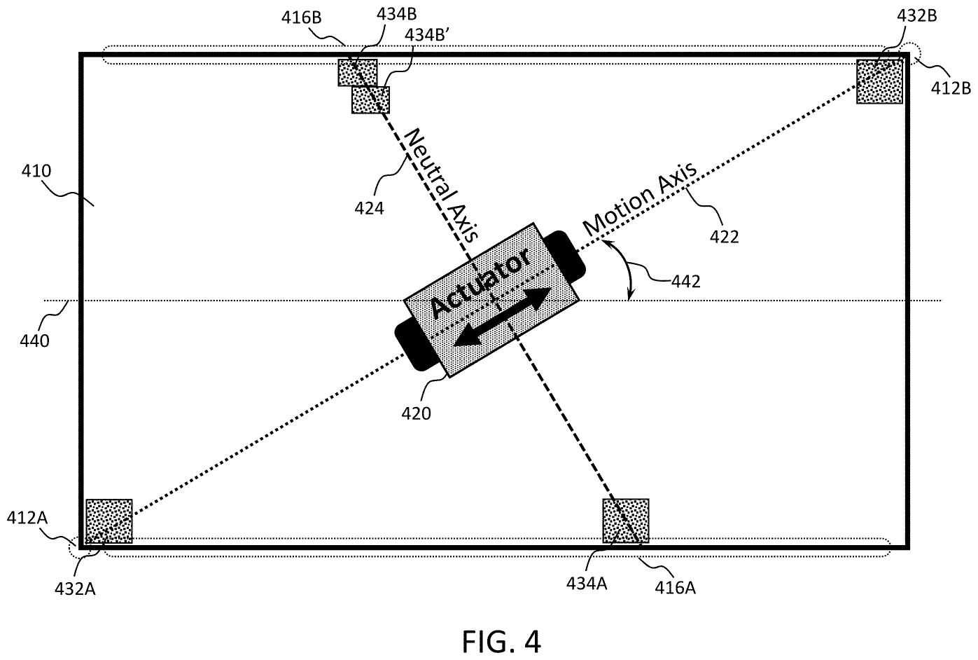

FIG. 4 is an illustration of an exemplary bottom-face view of the touch surface assembly 400 without a base, according to aspects hereof. The touch surface assembly 400 may be considered as a variation from the touch surface assembly 300 of FIG. 3. Thus, the features of a touch surface 410, a haptic actuator 420, and a first set of suspension components 432A, 432B may be similar to those of the touch surface 310, the haptic actuator 320, and the first set of suspension components 332A, 332B, respectively, as discussed above. For example, the actuator 420 forms an angle with respect to a centerline 440 such that a motion axis 422 of the haptic actuator 420 is located on a diagonal line between opposing corners 412A, 412B on the touch surface 410 and the first set of suspension components 412A, 412B are disposed near the opposing corners 412A, 412B, respectively. The touch surface assembly 400 is different from the touch surface assembly 300 of FIG. 3 in that the touch surface assembly 400 includes three suspension components for a second set of suspension components 434A, 434B, and 434B′ disposed on a neutral axis 424 of the haptic actuator 420. The suspension component 434A of the second set is disposed near a side 416A of the touch surface 410, and the suspension components 434B, 434B′ of the second set are disposed near an opposing side 416B of the touch surface 410. Although a number of the suspension components at one side of the motion axis 422 is different from a number of the suspension components at the other side of the motion axis 422, the size of each of the suspension components 434B, 434B′ is smaller than the size of the suspension component 434A to form a symmetry. In particular, as shown in FIG. 4, the size of the suspension components 434B, 434B′ combined is equal to the size of the suspension component 434A.

In some applications, referring back to FIG. 1A, the suspension component 130 may further include the third set of suspension components 136 in addition to the first set of suspension components 132 and the second set of suspension components 134, to further address any unwanted motion on the touch surface 110. In an aspect, the third set of suspension components 136 may be disposed on the touch surface 110 other than along or substantially along the motion axis and other than along or substantially along the neutral axis of the haptic actuator 120. As discussed above, a first set of suspension components 132 may be implemented mainly to address motion along a motion axis and a second set of suspension components 134 may be implemented mainly to address motion along a neutral axis. However, unwanted motion on the touch surface 110 may exist outside the vicinities of the motion axis and/or the neutral axis of the haptic actuator 120, which may not be sufficiently addressed by the first set of suspension components 132 and/or the second set of suspension components 134. Hence, the third set of suspension components 136 may be disposed outside the vicinities of the motion axis and/or the neutral axis of the haptic actuator 120 to address such an unwanted motion, thereby further optimizing a haptic effect provided by the haptic actuator 120. In an example where a touch surface 110 is a rectangle shape, if a set of suspension components is disposed on non-corner portions of the touch surface 110 while another set of suspension components is disposed only on two opposing corners of the touch surface 110, then the other two opposing corners of the touch surface 110 are not supported by any suspension components and thus may experience unwanted motion such as tipping over. For example, when there is a force exerted to the touch surface 110 such as a force from the haptic actuator 120 or a finger pressing down on the touch surface 110, such a force may cause the touch surface 110 to tip over if one or more corners of the touch surface 110 are not supported by any suspension components. Implementation of the third set of suspension components 136 disposed outside the motion axis and the neutral axis of the haptic actuator 120 may address such an unwanted motion on the touch surface 110 outside the motion axis and the neutral axis.

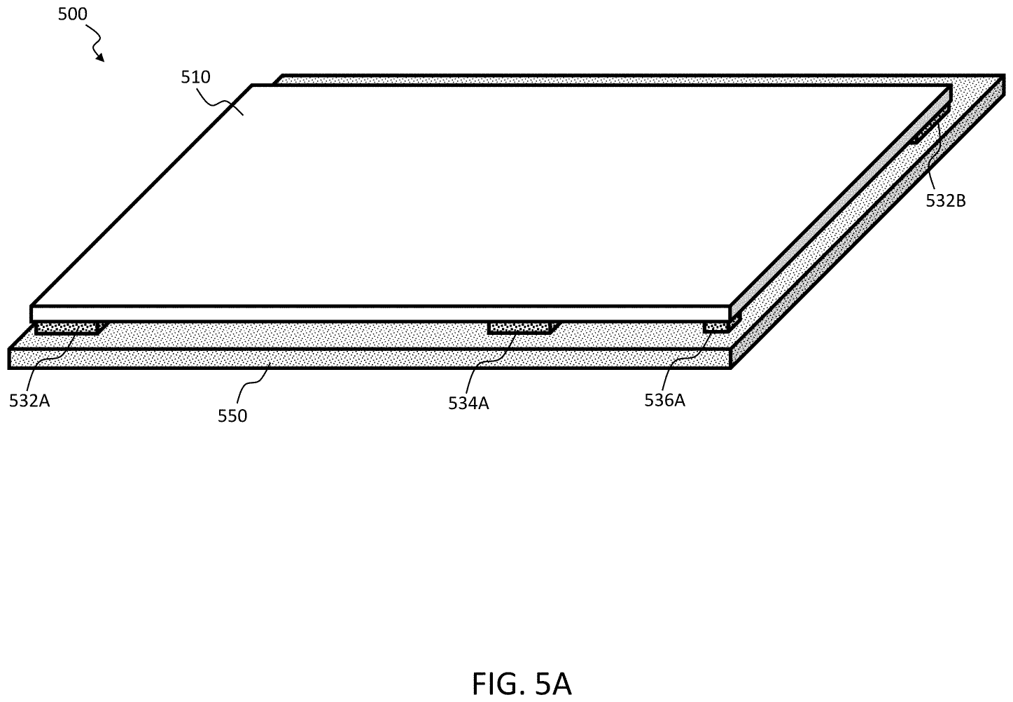

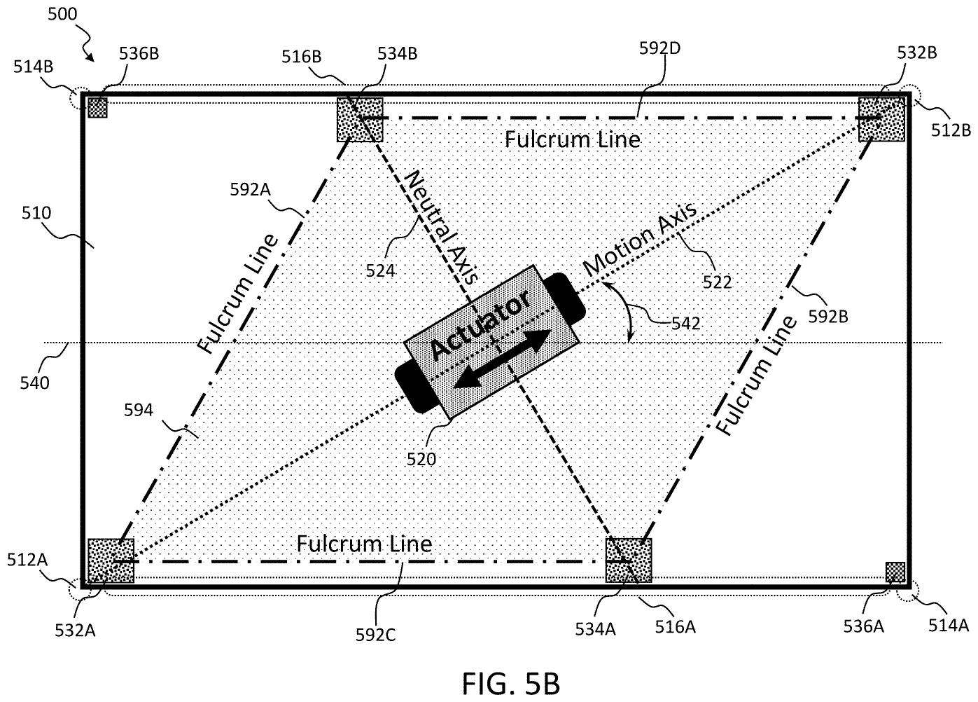

FIG. 5A is an illustration of a perspective view of a touch surface assembly 500, including first, second, and third sets of suspension components, according to aspects hereof. FIG. 5B is an illustration of an exemplary bottom-face view of the touch surface assembly 500 without a base, according to aspects hereof. The touch surface assembly 500 includes a touch surface 510, a first set of suspension components 532A, 532B and a second set of suspension components 534A, 534B, and a third set of suspension components 536A, 536B coupled to a bottom of the touch surface 510, and a haptic actuator 520 coupled to the bottom of the touch surface 510. The haptic actuator 520 is configured to provide a linear motion along a motion axis 522 of the haptic actuator 520 to provide a haptic effect on the touch surface 510, where the motion axis 522 is at angle from a centerline 540 of the touch surface 510.

The touch surface assembly 500 may also include a base 550 on which the touch surface 510 rests via the first set of suspension components 532A, 532B, the second set of suspension components 534A, 534B, and the third set of suspension components 536A, 536B. The touch surface assembly 500 may be an example of the touch surface assembly 100 of FIG. 1A. Therefore, the features of the touch surface 510, the haptic actuator 520, and the first set of suspension components 532A, 532B, the second set of suspension components 534A, 534B, the third set of suspension components 536A, 536B, and the base 550 may correspond to the touch surface 110, the haptic actuator 120, the first set of suspension components 132, the second set of suspension components 134, the third set of suspension components 136, and the base 150 of FIG. 1A and thus detailed discussions of the touch surface 510, the haptic actuator 520, and the first set of suspension components 532A, 532B, the second set of suspension components 534A, 534B, and the third set of suspension components 536A, 536B, and the base 550 are partially omitted for brevity.

The touch surface assembly 500 may be considered as a variation from the touch surface assembly 300 of FIGS. 3A and 3B. Thus, the features of the touch surface 510, the haptic actuator 520, and the first set of suspension components 532A, 532B, the second set of suspension components 534A, 534B may be similar to those of the touch surface 310, the haptic actuator 320, and the first set of suspension components 332A, 332B, and the second set of suspension components 334A, 334B, respectively, as discussed above. For example, the first set of suspension components 532A, 532B are disposed near first corners 512A, 512B, respectively, and the second set of suspension components 534A, 534B are disposed near opposing sides 516A, 516B, respectively. The first set of suspension components 532A, 532B are coupled to the touch surface 510 along or substantially along the motion axis 522, so as to address the motion on the touch surface 510 along the motion axis 522. The second set of suspension components 534A, 534B are coupled to the touch surface 510 along or substantially along a neutral axis 524 of the haptic actuator 520 that is perpendicular to the motion axis 522, so as to address the motion on the touch surface 510 along the neutral axis 524.

The touch surface assembly 500 is different from the touch surface assembly 300 of FIGS. 3A and 3B in that the touch surface assembly 500 has the third set of suspension components 536A, 536B. In an aspect, the third set of suspension components 536A, 536B may be disposed on the touch surface 510 other than along or substantially along the motion axis 522 and other than along or substantially along the neutral axis 524 of the haptic actuator 520, to address any unwanted motion such as unwanted motion outside of the vicinities of the motion axis 522 and the neutral axis 524. Hence, the third set of suspension components 536, 536B may address the unwanted motion on the touch surface 510 that may not be sufficiently addressed by the first set of suspension components 532A, 532B on the motion axis 522 and the second set of suspension components 534A, 534B on the neutral axis 524. In the example shown in FIGS. 5A and 5B, the third set of suspension components 536A, 536B are disposed near second corners 514A, 514B, outside of the motion axis 522 and the neutral axis 524, to address the unwanted motion outside of the motion axis 522 and the neutral axis 524.

Referring back to FIG. 1A, in order to determine locations of the third set of suspension components 136, imaginary fulcrum lines may be formed to estimate portions of the touch surface 110 that experience unwanted motion outside the portions corresponding to the motion axis and/or the neutral axis of the haptic actuator 120. In particular, the fulcrum lines may be formed by forming lines between the suspension components 132 of the first set and the suspension components 134 of the second set. For example, a fulcrum line may be formed by forming a line between a suspension component of the first set 132 and a suspension component of the second set 134. The fulcrum lines may define a fulcrum area enclosed by the fulcrum lines. In some aspects, the motion on the fulcrum lines and within the fulcrum area on the touch surface 110 may be addressed by the first set of suspension components 132 and the second set of suspension components 134, but portions of the touch surface 110 outside of the fulcrum area may also experience an unwanted motion that may not be sufficiently addressed by the first set of suspension components 132 and the second set of suspension components 134. Hence, in an aspect, the third set of suspension components 136 may be disposed outside of a fulcrum area defined by imaginary fulcrum lines formed between the suspension components 132 of the first set and the suspension components 134 of the second set. As such, the third set of suspension components 136 may address the unwanted motion on the touch surface 110 outside of the fulcrum area. For example, the unwanted motion on the touch surface 110 outside of the fulcrum area may be the motion substantially with respect to one or more of the fulcrum lines, such as a rotational motion substantially with respect to a fulcrum line. In this aspect, the third set of at least two suspension components may be configured to reduce movement of the touch surface 110 substantially about one or more of the plurality of imaginary fulcrum lines. The third set of suspension components 136 may reduce such unwanted motion on the touch surface 110 substantially with respect to the fulcrum lines.

In an aspect, the third set of suspension components 136 may be disposed at or near respective corners of the touch surface 110. If one or more corners of the touch surface 110 are not supported by any suspension component of the first set of suspension components 132 or the second set of suspension components 134, then such corners of the touch surface 110 should be supported by the third set of suspension components 136. If these corners are not supported by the third set of suspension components 136, the unwanted motion may occur outside the fulcrum area near these unsupported corners due to the lack of support in such corners of the touch surface 110. In the example mentioned above, if the touch surface 110 is a rectangle shape and the second set of suspension components 134 are disposed on non-corner portions of the touch surface 110 while the first set of suspension components 132 are disposed only on two corners of the touch surface 110, then the other two corners of the touch surface 110 that are supported by neither the first set of suspension components 132 nor the second set of suspension components 134 may be supported the third set of suspension components 136, to address any unwanted motion near the other two corners.

For example, as shown in FIG. 5B, a fulcrum line 592A is formed between the suspension component 532A of the first set and the suspension component 534B of the second set and a fulcrum line 592B is formed between the suspension component 532B of the first set and the suspension component 534A of the second set. Further, as shown in FIG. 5B, a fulcrum line 592C is formed between the suspension component 532A of the first set and the suspension component 534A of the second set and a fulcrum line 592D is formed between the suspension component 532B of the first set and the suspension component 534B of the second set. As shown in FIG. 5B, the fulcrum lines 592A-592D define a fulcrum area 594, which is a parallelogram area enclosed within the fulcrum lines 592A-592D.

The third set of suspension components 536A, 536B are disposed outside of the fulcrum area 594, to further reduce or eliminate unwanted motion on the touch surface 510. The third set of suspension components 536A, 536 may address the unwanted motion outside of the fulcrum area 594, which may not be sufficiently addressed by the first set of suspension components 532A, 532B and the second set of suspension components 534A, 534B. For example, without the third set of suspension components 536A, 536B, portions of the touch surface 510 that are outside of the fulcrum area 594 may move substantially about one or more of the fulcrum lines 592A-592D when a force is exerted on the touch surface 510, for example, by the haptic actuator 520 and/or a finger pressing on the touch surface 510. In particular, without the suspension component 536B of the third set, the upper left portion from the fulcrum line 592A on the touch surface 510 may move substantially about the fulcrum line 592A, for example, by tipping over substantially with respect to the fulcrum line 592A when a force is exerted on the upper left portion. Further, without the suspension component 536A of the third set, the bottom right portion from the fulcrum line 592B on the touch surface 510 may move substantially about the fulcrum line 592B, for example, by tipping over substantially with respect to the fulcrum line 592B when a force is exerted on the bottom right portion. Thus, the suspension components 536A of the third set may reduce or eliminate the unwanted movement of the touch surface 510 substantially about the fulcrum line 592B, and the suspension component 536B of the third set may reduce or eliminate the unwanted movement of the touch surface 510 substantially about the fulcrum line 592A. On the other hand, the portion above the fulcrum line 592D and the portion below the fulcrum line 592C on the touch surface 510 may not substantially move because these portions are small portions and the fulcrum lines 592D and the fulcrum line 592C are close to the boundaries of the touch surface 510. As such, a suspension component may not be necessary above the fulcrum line 592D or the fulcrum line 592C on the touch surface 510.

In an aspect, referring back to FIG. 1A, each of the suspension components 136 of the third set may be smaller than each of the suspension components 132 of the first set and each of the suspension components of the second set 134. By making the suspension components 136 of the third set to be small, any adverse effect from asymmetry of the suspension components 136 of the third set, if any, may be negligible. For example, an area of the touch surface 110 covered by each of the suspension components 136 of the third set may be less than or equal to 1/10 of an area of the touch surface 110 covered by a suspension component of the first set 132 or a suspension component of the second set 134. For example, if the unwanted motion addressed by the third set of suspension components 136 is smaller than the unwanted motion addressed by the first set of suspension components and/or the second set of suspension components, the third set of suspension components 136 may be proportionally smaller than the first set of suspension components and/or the second set of suspension components.

In the example shown in FIGS. 5A and 5B, the third set of suspension components 536A, 536B are disposed near respective second corners 514A, 514B of the touch surface 510. As discussed above, a size of each suspension component of the third set of suspension components 536A, 536B may not need to be equal to a size of a suspension component of the first set of suspension components 532A, 532B and/or a size of a suspension component of the second set of suspension components 534A, 534B. In the example shown in FIGS. 5A and 5B, each of the suspension components 536A, 536B of the third set is smaller than each of the suspension components of the first set and each of the suspension components of the second set.

In an aspect, referring back to FIG. 1A, the third set of suspension components 136 may be necessary depending on a type of suspension components used for the first set of suspension components 132 and/or the second set of suspension components 134. For example, if the first set of suspension components 132 and/or the second set of suspension components 134 each includes a flexure, the third set of suspension components 136 may not be necessary because the flexure may provide a strong support for the touch surface 110, compared to an elastomer.

In an aspect, the processor 170 may be configured to communicate with and/or to control the touch surface 110, for example, as a controller, and/or the haptic actuator 120. For example, the touch surface 110 may receive a touch input and communicate information about the touch input to the processor 170 that can perform one or more tasks based on the touch input. For example, the processor 170 may control the operation of the haptic actuator 120, e.g., to activate the haptic actuator 120 to provide a haptic effect and deactivate the haptic actuator 120 for braking. The processor 170 may be configured to generate a control signal to control the touch surface 110 and/or the haptic actuator 120 by executing instructions, for example, stored in memory 180. The processor 170 may, in an embodiment, be implemented as one or more processors, for example, a microprocessor, a field programmable gate array (FPGA), application specific integrated circuit (ASIC), programmable logic array (PLA), or other control circuit. The processor 170 may be part of a general purpose control circuit for a main device where the touch surface assembly 100 is implemented or the processor 170 may be a processor dedicated to controlling the touch surface assembly 100.

In an aspect, the touch surface assembly 100 may include a memory 180, as a data storage component. The memory 180 may be a flexible memory. In an embodiment, the memory 180 may be a non-transitory computer-readable medium, and may include read-only memory (ROM), random access memory (RAM), a solid state drive (SSD), a hard drive, a flash memory, or other type of memory. In FIG. 1, the memory 180 may store instructions that can be executed by the processor 170 to generate a control signal, such as a trigger signal, as a trigger for the haptic feedback according to an embodiment described herein. In an embodiment, the memory 180 may store other information and/or modules.

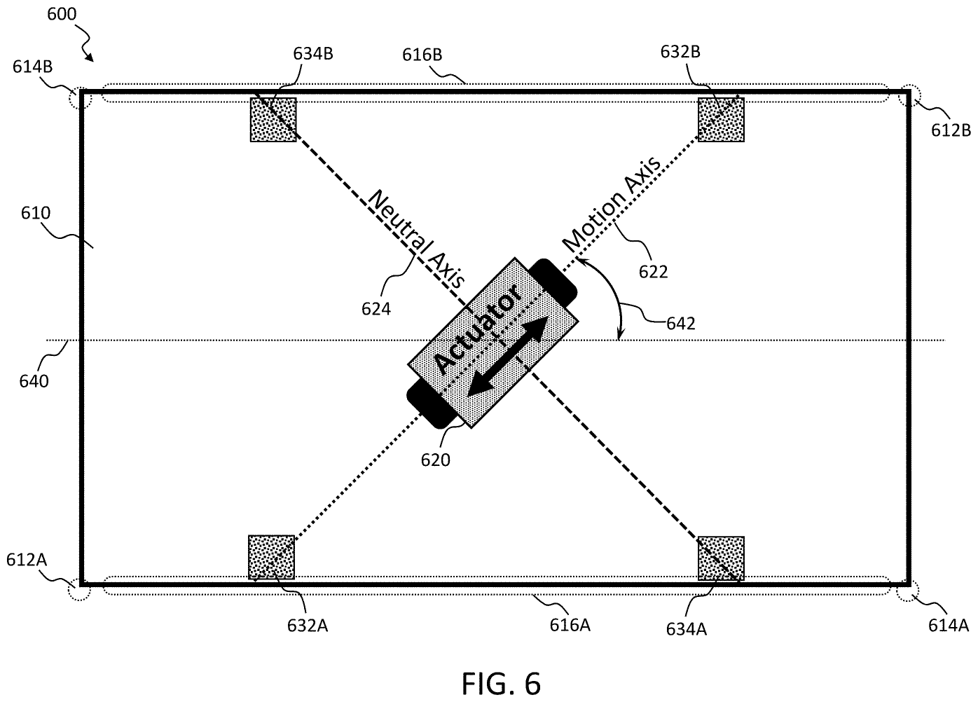

FIG. 6 is an illustration of an exemplary bottom-face view of the touch surface assembly 600 without a base, according to aspects hereof. In FIG. 6, an actuator 620 is rotated more in a counter-clockwise direction compared to the actuator 320 shown in FIG. 3B to form an angle 642 between a centerline 640 and a motion axis 622, and thus the motion axis 622 in FIG. 6 is not located on a diagonal line between the opposing corners 612A, 612B of a touch surface 610. In particular, in FIG. 6, a neutral axis 624 crosses opposing sides 616A, 616B that form a portion of a perimeter of the touch surface 610, without crossing the opposing corners 614A, 614B of the touch surface 610, and the motion axis 622 also crosses the opposing sides 616A, 616B. Because of a shape of the touch surface 610 and the orientation of the haptic actuator 620 on the touch surface 610, the second set of suspension components 634A, 634B are disposed near opposing sides 616A, 616B of the touch surface 610, respectively, and the first set of suspension components 632A, 632B are disposed near opposing sides 616A, 616B of the touch surface 610, respectively.

The haptic actuator 620 is configured to provide a linear motion along the motion axis 622 of the haptic actuator 620 to provide a haptic effect on the touch surface 610, where the motion axis 622 is at angle from a centerline 640 of the touch surface 610. The first set of suspension components 632A, 632B are coupled to the touch surface 610 along or substantially along the motion axis 622, so as to address any unwanted motion on the touch surface 610 along the motion axis 622. The second set of suspension components 634A, 634B are coupled to the touch surface 610 along the neutral axis 624 of the haptic actuator 620 that is perpendicular to the motion axis 622, so as to address the motion on the touch surface 610 along the neutral axis 624.

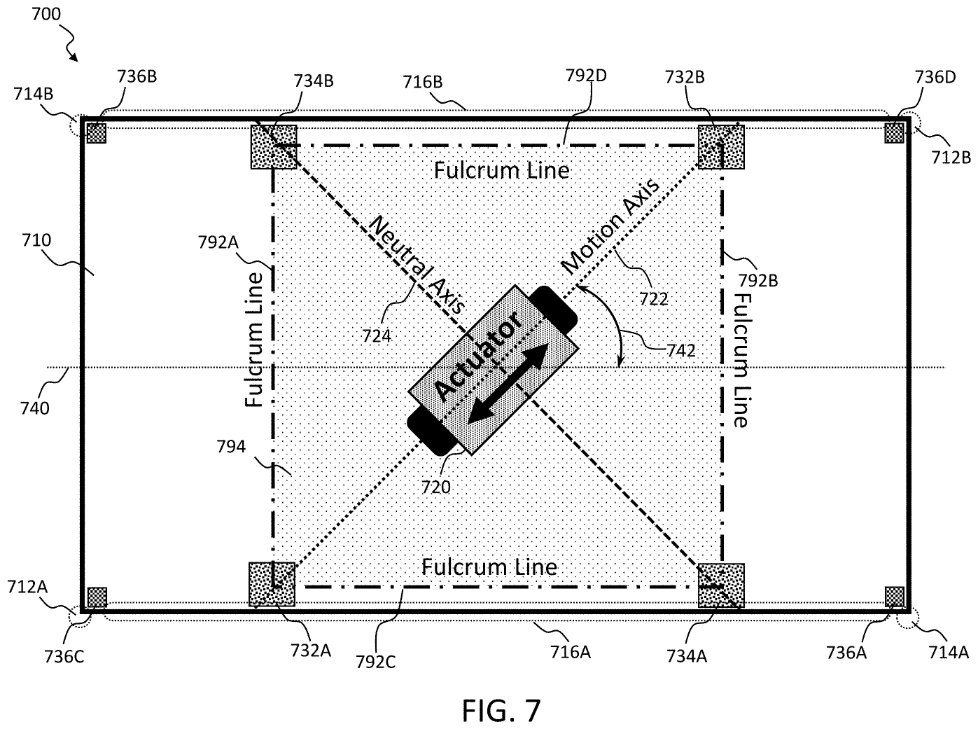

FIG. 7 is an illustration of an exemplary bottom-face view of the touch surface assembly 700 without a base, according to aspects hereof. The touch surface assembly 700 includes the touch surface 710, a first set of suspension components 732A, 732B and a second set of suspension components 734A, 734B, and a third set of suspension components 736A, 736B, 736C, 736D coupled to a bottom of the touch surface 710, and a haptic actuator 720 coupled to the bottom of the touch surface 710. The haptic actuator 720 is configured to provide a linear motion along a motion axis 722 of the haptic actuator 720 to provide a haptic effect on the touch surface 710, where the motion axis 722 is at angle from a centerline 740 of the touch surface 710.

Although not shown in FIG. 7, the touch surface assembly 700 may also include a base, for example, base 150 of FIG. 1A on which the touch surface 710 rests via the first set of suspension components 732A, 732B, the second set of suspension components 734A, 734B, and the third set of suspension components 736A, 736B, 736C, 736D. The touch surface assembly 700 may be an example of the touch surface assembly 100 of FIG. 1A. Therefore, the features of the touch surface 710, the haptic actuator 720, and the first set of suspension components 732A, 732B, the second set of suspension components 734A, 734B, and the third set of suspension components 736A, 736B, 736C, 736D may correspond to the touch surface 110, the haptic actuator 120, the first set of suspension components 132, the second set of suspension components 134, and the third set of suspension components 136 of FIG. 1A and thus detailed discussions of the touch surface 710, the haptic actuator 720, and the first set of suspension components 732A, 732B, the second set of suspension components 734A, 734B, and the third set of suspension components 736A, 736B, 736C, 736D are partially omitted for brevity.

The touch surface assembly 700 may be considered as a variation from the touch surface assembly 600 of FIG. 6. Thus, the features of the touch surface 710, the haptic actuator 720, the first set of suspension components 732A, 732B, and the second set of suspension components 734A, 734B may be similar to those of the touch surface 610, the haptic actuator 620, the first set of suspension components 632A, 632B, and the second set of suspension components 634A, 634B, respectively, as discussed above. For example, the second set of suspension components 734A, 734B are disposed near opposing sides 716A, 716B of the touch surface 710, respectively, and the first set of suspension components 732A, 732B are disposed near opposing sides 716A, 716B of the touch surface 710, respectively.

The haptic actuator 720 is configured to provide a linear motion along a motion axis 722 of the haptic actuator 720 to provide a haptic effect on the touch surface 710, where the motion axis 722 is at angle from a centerline 740 of the touch surface 710. The first set of suspension components 732A, 732B are coupled to the touch surface 710 along or substantially along the motion axis 722, so as to address the motion on the touch surface 710 along the motion axis 722. The second set of suspension components 734A, 734B are coupled to the touch surface 710 along or substantially along a neutral axis 724 of the haptic actuator 720 that is perpendicular to the motion axis 722, so as to address the motion on the touch surface 710 along the neutral axis 724.

The touch surface assembly 700 is different from the touch surface assembly 600 of FIG. 6 in that the touch surface assembly 700 has the third set of suspension components 736A, 736B, 736C, 736D near corners 712A, 712B, 714A, 714B, respectively. The first set of suspension components 732A, 732B are coupled to the touch surface 710 along or substantially along the motion axis 722, so as to address the motion on the touch surface 710 along the motion axis 722. The second set of suspension components 734A, 734B are coupled to the touch surface 710 along or substantially along a neutral axis 724 of the haptic actuator 720 that is perpendicular to the motion axis 722, so as to address the motion on the touch surface 710 along the neutral axis 724. However, there may be an unwanted motion on the touch surface 710 that may not be sufficiently addressed by the first set of suspension components 732A, 732B on the motion axis 722 and the second set of suspension components 734A, 734B on the neutral axis 724. Thus, the third set of suspension components 736A, 736B are disposed on the touch surface 710 other than along or substantially along the motion axis 722 and other than along or substantially along the neutral axis 724 of the haptic actuator 720, to address this unwanted motion. In the example shown in FIG. 7, the third set of suspension components 736A, 736B, 736C, 736D are disposed near corners 712A, 712B, 714A, 714B, respectively, outside of the motion axis 722 and the neutral axis 724.

In FIG. 7, a fulcrum line 792A is formed between the suspension component 732A of the first set and the suspension component 734B of the second set and a fulcrum line 792B is formed between the suspension component 732B of the first set and the suspension component 734A of the second set. Further, as shown in FIG. 7, a fulcrum line 792C is formed between the suspension component 732A of the first set and the suspension component 734A of the second set and a fulcrum line 792D is formed between the suspension component 732B of the first set and the suspension component 734B of the second set. As shown in FIG. 7B, the fulcrum lines 792A-792D define a fulcrum area 794, which is a square area enclosed within the fulcrum lines 792A-792D.

The motion occurring outside of the fulcrum area 794 may not be sufficiently addressed by the first set of suspension components 732A, 732B and the second set of suspension components 734A, 734B. The third set of suspension components 736A, 736B, 736C, 736D are disposed outside of the fulcrum area 794, to address the motion outside of the fulcrum area 794. For example, without the third set of suspension components 736A, 736B, 736C, 736D, portions of the touch surface 710 that are outside of the fulcrum area 794 may move substantially about one or more of the fulcrum lines 792A-792D when a force is exerted on the touch surface 710, for example, by the haptic actuator 520 and/or a finger pressing on the touch surface 510. In particular, without the suspension components 736B, 736C, the left side from the fulcrum line 792A on the touch surface 710 may move substantially about the fulcrum line 792A, for example, by tipping over substantially with respect to the fulcrum line 792A. Further, without the suspension components 736A, 736D, the right side of the fulcrum line 792B on the touch surface 710 may move substantially about the fulcrum line 792B, for example, by tipping over substantially with respect to the fulcrum line 792B. Thus, the suspension components 736A, 736D of the third set are configured to reduce movement of the touch surface 710 substantially about the fulcrum line 792B, and the suspension components 736B, 736C of the third set are configured to reduce movement of the touch surface 710 substantially about the fulcrum line 792A. On the other hand, the portion above the fulcrum line 792D and the portion below the fulcrum line 792C on the touch surface 710 may not substantially move because these portions are small portions and the fulcrum lines 792D and the fulcrum line 792C are close to the boundaries of the touch surface 710. As such, a suspension component may not be necessary above the fulcrum line 792D or the fulcrum line 792C on the touch surface 710.

In the example shown in FIG. 7, the third set of suspension components 736A, 736B, 736C, 736D are disposed near respective corners 714A, 714B, 712A, 712B of the touch surface 710. As discussed above, a size of each suspension component of the third set of suspension components 736A, 736B, 736C, 736D may not need to be equal to a size of a suspension component of the first set of suspension components 732A, 732B and/or a size of a suspension component of the second set of suspension components 734A, 734B. In the example shown in FIG. 7, each of the suspension components 736A, 736B, 736C, 736D of the third set is smaller than each of the suspension components of the first set and each of the suspension components of the second set.

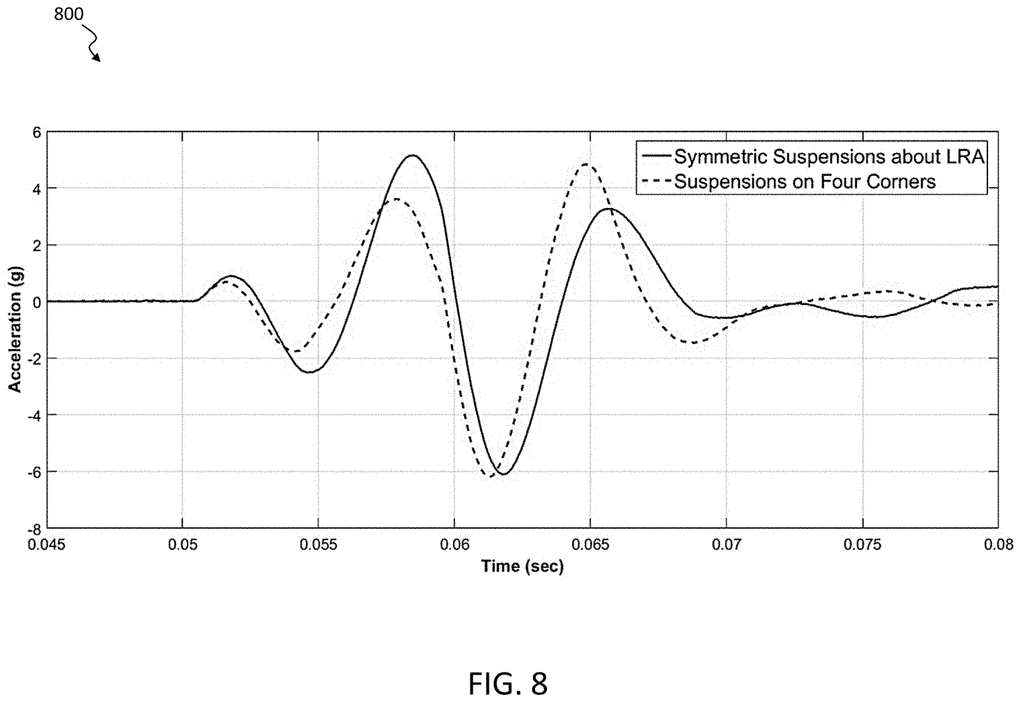

FIG. 8 illustrates experimental results using the touch surface assembly of the disclosure, according to aspects hereof. The solid line shows the results using the touch surface assembly according to aspects herein, for example, the touch surface assembly of FIG. 1A, with the suspension components disposed along the motion axis and the neutral axis of the haptic actuator. The dotted line shows the results using the touch surface assembly without suspension components along the neutral axis of the haptic actuator, for example, the touch surface assembly 200 of FIGS. 2A and 2B. Three major peaks are shown after the haptic actuator's activation at 0.05 seconds, where the braking of the haptic actuator occurs around 0.06 seconds. The dotted line shows that the major peak at 0.065 seconds after the braking is higher than the other major peaks, which shows that the braking of the haptic actuator is not effectively performed. On the other hand, the solid line shows that the major peak around 0.066 seconds after braking is significantly lower than the major peak before braking at 0.058 seconds, which shows that the braking becomes effective immediately after the braking has occurred. Further, as shown in FIG. 8, at 0.058 seconds, the solid line shows a higher peak than the dotted line before braking because the touch surface assembly according to aspects herein allows the mechanical energy of the haptic actuator 120 to be focused only or mostly on the motion axis of the haptic actuator 120, without being dispersed to other axes.

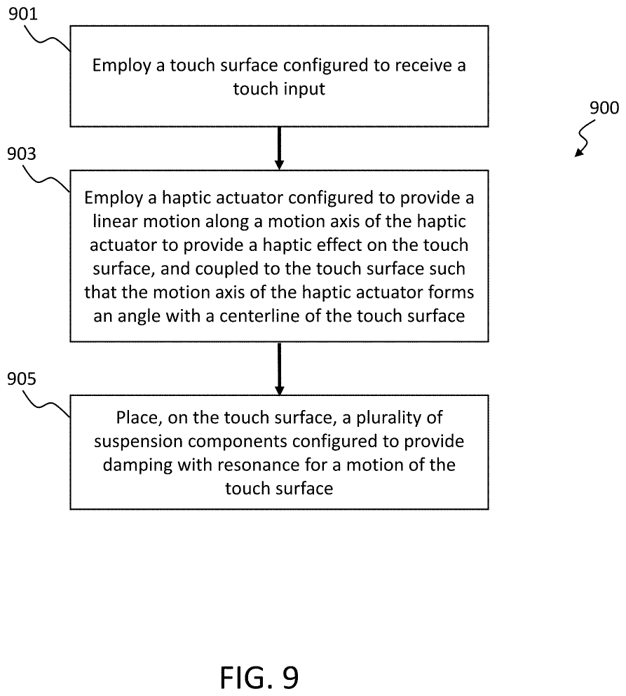

FIG. 9 depicts a flow diagram for a method 900 for providing a touch surface with a haptic capability, according to aspects hereof. At 901, the method 900 employs a touch surface 110 configured to receive a touch input. At 903, the method 900 employs a haptic actuator 120 configured to provide a linear motion along a motion axis of the haptic actuator 120 to provide a haptic effect on the touch surface 110, and coupled to the touch surface 110 such that the motion axis of the haptic actuator 120 forms an angle with a centerline of the touch surface 110. At 905, the method 900 places, on the touch surface 110, a plurality of suspension components 130 configured to provide damping with resonance for a motion of the touch surface 110. In an aspect, a first set of at least two suspension components of the plurality of suspension components are coupled to the touch surface along or substantially along the motion axis of the haptic actuator, and a second set of at least two suspension components of the plurality of suspension components are coupled to the touch surface along or substantially along a neutral axis of the haptic actuator that is perpendicular to the motion axis.

In an aspect, the following example steps may be taken to provide the touch surface with the haptic capability. First, the geometry of the touch surface 110 is determined, e.g., by determining a size and a shape of the touch surface 110. Then, the orientation of the haptic actuator 120 on the touch surface 110 is determined, to provide a haptic effect on the touch surface 110. For example, the orientation of the haptic actuator 120 may dispose the haptic actuator 120 at a center of the touch surface 110 at an angle from a centerline of the touch surface 110, such as a 45-degree angle, an angle of a diagonal direction, or any other configuration. Subsequently, locations for the first set of suspension components 132 on the motion axis of the haptic actuator 120 and the second set of suspension components 134 the neutral axis of the haptic actuator 120 are determined, and the first set of suspension components 132 and the second set of suspension components 134 are placed on such locations. The locations are determined such that the first set of suspension components 132 are symmetric or nearly symmetric to each other with respect to the neutral axis and the second set of suspension components 134 are symmetric or nearly symmetric to each other with respect to the motion axis. In an example, the locations of the first set of suspension components 132 may be at or near intersections of the motion axis and boundaries of the touch surface 110, and the locations of the second set of suspension components 134 may be at or near intersections of the neutral axis and boundaries of the touch surface 110.

Optionally, fulcrum lines may be determined, where the touch surface 110 experience an unwanted motion, for example, tipping over, substantially with respect to one or more of the fulcrum lines, and the third set of suspension components 136 may be placed on the touch surface 110 to reduce or eliminate the unwanted motion substantially with respect to one or more of the fulcrum lines, due to a force on the touch surface 110 outside of the fulcrum lines.

### ADDITIONAL DISCUSSION OF VARIOUS EMBODIMENTS

Embodiment 1 relates to a touch surface assembly with a haptic capability, comprising: a touch surface configured to receive a touch input; a haptic actuator configured to provide a linear motion along a motion axis of the haptic actuator to provide a haptic effect on the touch surface, and coupled to the touch surface such that the motion axis of the haptic actuator forms an angle with a centerline of the touch surface; and a plurality of suspension components configured to provide damping with resonance for a motion of the touch surface, wherein a first set of at least two suspension components of the plurality of suspension components are coupled to the touch surface along or substantially along the motion axis of the haptic actuator, and wherein a second set of at least two suspension components of the plurality of suspension components are coupled to the touch surface along or substantially along a neutral axis of the haptic actuator that is perpendicular to the motion axis.

Embodiment 2 includes the touch surface assembly of embodiment 1, wherein the second set of at least two suspension components of the plurality of suspension components are disposed on the touch surface along or substantially along the neutral axis to be substantially symmetric to each other with respect to the motion axis.

Embodiment 3 includes the touch surface assembly of embodiment 1 or 2, wherein the first set of at least two suspension components of the plurality of suspension components are disposed on the touch surface along or substantially along the motion axis to be substantially symmetric to each other with respect to the neutral axis.

Embodiment 4 includes the touch surface assembly of any one of embodiments 1-3. wherein a first portion of the touch surface located on one side of the motion axis and a second portion of the touch surface located on an opposite side of the motion axis are asymmetric to each other with respect to the motion axis.

Embodiment 5 includes the touch surface assembly of any one of embodiments 1-4, wherein a third portion of the touch surface located on one side of the neutral axis and a fourth portion of the touch surface located on an opposite side of the neutral axis are asymmetric to each other with respect to the neutral axis.

Embodiment 6 includes the touch surface assembly of any one of embodiments 1-5, wherein corners of the touch surface are asymmetrically disposed to each other with respect to either of the motion axis or the neutral axis.

Embodiment 7 includes the touch surface assembly of any one of embodiments 1-6, wherein the at least two suspension components of the second set are disposed at or near opposing sides of the touch surface, respectively.

Embodiment 8 includes the touch surface assembly of any one of embodiments 1-7, wherein the haptic actuator is disposed on the touch surface such that the motion axis of the haptic actuator is located on a diagonal line between two corners on the touch surface.

Embodiment 9 includes the touch surface assembly of any one of embodiments 1-8, wherein the at least two suspension components of the first set are disposed at or near the opposing sides of the touch surface, respectively.

Embodiment 10 includes the touch surface assembly of any one of embodiments 1-9, wherein each of the plurality of suspension components includes at least one of an elastomer device, a flexure, or a spring-based device.

Embodiment 11 includes the touch surface assembly of any one of embodiments 1-10, wherein a third set of at least two suspension components of the plurality of suspension components are disposed on the touch surface other than along or substantially along the motion axis and other than along or substantially along the neutral axis of the haptic actuator.

Embodiment 12 includes the touch surface assembly of embodiment 11, wherein the third set of at least two suspension components are disposed outside of a fulcrum area defined by a plurality of imaginary fulcrum lines formed between the at least two suspension components of the first set and the at least two suspension components of the second set.

Embodiment 13 includes the touch surface assembly of embodiment 12, wherein the third set of at least two suspension components are configured to reduce movement of the touch surface substantially about one or more of the plurality of imaginary fulcrum lines.

Embodiment 14 includes the touch surface assembly of any one of embodiments 11-13, wherein the at least two suspension components of the third set are disposed at or near respective corners of the touch surface.

Embodiment 15 includes the touch surface assembly of any one of embodiments 11-14, wherein each of the at least two suspension components of the third set is smaller than each of the at least two suspension components of the first set and each of the at least two suspension components of the second set.

Embodiment 16 includes the touch surface assembly of any one of embodiments 11-15, further comprising a base coupled to the touch surface via the plurality of suspension components.

Embodiment 17 includes the touch surface assembly of any one of embodiments 11-16, wherein the haptic actuator includes at least one of a linear resonant actuator or a direct-drive actuator.

Embodiment 18 relates to a method of providing a touch surface assembly with a haptic capability, comprising: employing a touch surface configured to receive a touch input; employing a haptic actuator configured to provide a linear motion along a motion axis of the haptic actuator to provide a haptic effect on the touch surface, and coupled to the touch surface such that the motion axis of the haptic actuator forms an angle with a centerline of the touch surface; placing, on the touch surface, a plurality of suspension components configured to provide damping with resonance for a motion of the touch surface, wherein a first set of at least two suspension components of the plurality of suspension components are coupled to the touch surface along or substantially along the motion axis of the haptic actuator, and wherein a second set of at least two suspension components of the plurality of suspension components are coupled to the touch surface along or substantially along a neutral axis of the haptic actuator that is perpendicular to the motion axis.

Embodiment 19 includes the method of embodiment 18, wherein the second set of at least two suspension components of the plurality of suspension components are disposed on the touch surface along or substantially along the neutral axis to be substantially symmetric to each other with respect to the motion axis.

Embodiment 20 includes the method of embodiment 18 or 20, wherein the first set of at least two suspension components of the plurality of suspension components are disposed on the touch surface along or substantially along the motion axis to be substantially symmetric to each other with respect to the neutral axis.

Embodiment 21 includes the method of any one of embodiments 18-20. wherein a first portion of the touch surface located on one side of the motion axis and a second portion of the touch surface located on an opposite side of the motion axis are asymmetric to each other with respect to the motion axis.

Embodiment 22 includes the method of any one of embodiments 18-21, wherein a third portion of the touch surface located on one side of the neutral axis and a fourth portion of the touch surface located on an opposite side of the neutral axis are asymmetric to each other with respect to the neutral axis.

Embodiment 23 includes the method of any one of embodiments 18-22, wherein corners of the touch surface are asymmetrically disposed to each other with respect to either of the motion axis or the neutral axis.

Embodiment 24 includes the method of any one of embodiments 18-23, wherein the at least two suspension components of the second set are disposed at or near opposing sides of the touch surface, respectively.

Embodiment 25 includes the method of any one of embodiments 18-24, wherein the haptic actuator is disposed on the touch surface such that the motion axis of the haptic actuator is located on a diagonal line between two corners on the touch surface.

Embodiment 26 includes the method of any one of embodiments 18-25, wherein the at least two suspension components of the first set are disposed at or near the opposing sides of the touch surface, respectively.

Embodiment 27 includes the method of any one of embodiments 18-26, wherein each of the plurality of suspension components includes at least one of an elastomer device, a flexure, or a spring-based device.

Embodiment 28 includes the method of any one of embodiments 18-27, wherein a third set of at least two suspension components of the plurality of suspension components are disposed on the touch surface other than along or substantially along the motion axis and other than along or substantially along the neutral axis of the haptic actuator.

Embodiment 29 includes the method of embodiment 28, wherein the third set of at least two suspension components are disposed outside of a fulcrum area defined by a plurality of imaginary fulcrum lines formed between the at least two suspension components of the first set and the at least two suspension components of the second set.

Embodiment 30 includes the method of embodiment 29, wherein the third set of at least two suspension components are configured to reduce movement of the touch surface substantially about one or more of the plurality of imaginary fulcrum lines.

Embodiment 31 includes the method of any one of embodiments 28-30, wherein the at least two suspension components of the third set are disposed at or near respective corners of the touch surface.

Embodiment 32 includes the method of any one of embodiments 28-31, wherein each of the at least two suspension components of the third set is smaller than each of the at least two suspension components of the first set and each of the at least two suspension components of the second set.

Embodiment 33 includes the method of any one of embodiments 28-32, further comprising a base coupled to the touch surface via the plurality of suspension components.

Embodiment 34 includes the method of any one of embodiments 28-33, wherein the haptic actuator includes at least one of a linear resonant actuator or a direct-drive actuator.

While various embodiments have been described above, it should be understood that they have been presented only as illustrations and examples of the present invention, and not by way of limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the appended claims and their equivalents. It will also be understood that each feature of each embodiment discussed herein, and of each reference cited herein, can be used in combination with the features of any other embodiment. All patents and publications discussed herein are incorporated by reference herein in their entirety.

What is claimed is:

1. A touch surface assembly with a haptic capability, comprising:
a touch surface configured to receive a touch input;
a haptic actuator configured to provide a linear motion along a motion axis of the haptic actuator to provide a haptic effect on the touch surface, and coupled to the touch surface such that the motion axis of the haptic actuator forms an angle with a centerline of the touch surface; and
a plurality of suspension components configured to provide damping with resonance for a motion of the touch surface,
wherein a first set of at least two suspension components of the plurality of suspension components are coupled to the touch surface along or substantially along the motion axis of the haptic actuator, and
wherein a second set of at least two suspension components of the plurality of suspension components are coupled to the touch surface along or substantially along a neutral axis of the haptic actuator that is perpendicular to the motion axis.

2. The touch surface assembly of claim 1, wherein the second set of at least two suspension components of the plurality of suspension components are disposed on the touch surface along or substantially along the neutral axis to be substantially symmetric to each other with respect to the motion axis.

3. The touch surface assembly of claim 2, wherein the first set of at least two suspension components of the plurality of suspension components are disposed on the touch surface along or substantially along the motion axis to be substantially symmetric to each other with respect to the neutral axis.

4. The touch surface assembly of claim 1, wherein a first portion of the touch surface located on one side of the motion axis and a second portion of the touch surface located on an opposite side of the motion axis are asymmetric to each other with respect to the motion axis.

5. The touch surface assembly of claim 4, wherein a third portion of the touch surface located on one side of the neutral axis and a fourth portion of the touch surface located on an opposite side of the neutral axis are asymmetric to each other with respect to the neutral axis.

6. The touch surface assembly of claim 1, wherein corners of the touch surface are asymmetrically disposed to each other with respect to either of the motion axis or the neutral axis.

7. The touch surface assembly of claim 1, wherein the at least two suspension components of the second set are disposed at or near opposing sides of the touch surface, respectively.

8. The touch surface assembly of claim 7, wherein the haptic actuator is disposed on the touch surface such that the motion axis of the haptic actuator is located on a diagonal line between two corners on the touch surface.

9. The touch surface assembly of claim 7, wherein the at least two suspension components of the first set are disposed at or near the opposing sides of the touch surface, respectively.

10. The touch surface assembly of claim 1, wherein each of the plurality of suspension components includes at least one of an elastomer device, a flexure, or a spring-based device.

11. The touch surface assembly of claim 1, wherein a third set of at least two suspension components of the plurality of suspension components are disposed on the touch surface other than along or substantially along the motion axis and other than along or substantially along the neutral axis of the haptic actuator.

12. The touch surface assembly of claim 11, wherein the third set of at least two suspension components are disposed outside of a fulcrum area defined by a plurality of imaginary fulcrum lines formed between the at least two suspension components of the first set and the at least two suspension components of the second set.

13. The touch surface assembly of claim 12, wherein the third set of at least two suspension components are configured to reduce movement of the touch surface substantially about one or more of the plurality of imaginary fulcrum lines.

14. The touch surface assembly of claim 11, wherein the at least two suspension components of the third set are disposed at or near respective corners of the touch surface.

15. The touch surface assembly of claim 11, wherein each of the at least two suspension components of the third set is smaller than each of the at least two suspension components of the first set and each of the at least two suspension components of the second set.

16. The touch surface assembly of claim 1, further comprising a base coupled to the touch surface via the plurality of suspension components.

17. The touch surface assembly of claim 1, wherein the haptic actuator includes at least one of a linear resonant actuator or a direct-drive actuator.

18. A method of providing a touch surface assembly with a haptic capability, comprising:
employing a touch surface configured to receive a touch input;
employing a haptic actuator configured to provide a linear motion along a motion axis of the haptic actuator to provide a haptic effect on the touch surface, and coupled to the touch surface such that the motion axis of the haptic actuator forms an angle with a centerline of the touch surface;
placing, on the touch surface, a plurality of suspension components configured to provide damping with resonance for a motion of the touch surface,
wherein a first set of at least two suspension components of the plurality of suspension components are coupled to the touch surface along or substantially along the motion axis of the haptic actuator, and
wherein a second set of at least two suspension components of the plurality of suspension components are coupled to the touch surface along or substantially along a neutral axis of the haptic actuator that is perpendicular to the motion axis.

19. The method of claim 18, wherein a third set of at least two suspension components of the plurality of suspension components are disposed on the touch surface other than along or substantially along the motion axis and other than along or substantially along the neutral axis of the haptic actuator.

20. The method of claim 19, wherein the third set of at least two suspension components are disposed outside of a fulcrum area defined by a plurality of imaginary fulcrum lines formed between the at least two suspension components of the first set and the at least two suspension components of the second set.
